(19) United States
(12) Patent Application Publication
(10) Pub. No.: US 2005/0073875 A1
(43) Pub. Date: Apr. 7, 2005

(54) Redundancy repaired yield calculation method

(75) Inventor: Yoko Tohyama, Kyoto (JP)

Correspondence Address: Jack Q. Lever, Jr.;McDERMOTT, WILL & EMERY, 600 Thirteenth Street, N.W., Washington, DC, 20005-3096, US

(73) Assignee: MATSUSHITA ELECTRIC INDUSTRIAL CO., LTD.

(21) Appl. No.: 10/954,283

(22) Filed: Oct. 1, 2004

(30) Foreign Application Priority Data
Oct. 3, 2003 (JP) 2003-345267

(51) Int. Cl. G11C 11/00

(52) U.S. Cl. 365/154

(57) ABSTRACT

A product of a probability that failure-related defects in the number larger than the number of redundancy repairs occur in one layer included in a memory cell array and a probability that no failure-related defect occurs in the other layers of the memory cell array is used for calculating a yield.

### BACKGROUND OF THE INVENTION

The present invention relates to a method for calculating a yield attained when a memory cell array is provided with redundancy repair.

Recently, circuits have become more and more complicated because of the increased degree of integration and improved performance of integrated circuits, and as a result, it has become difficult to calculate a yield on the basis of a chip size alone as in conventional technique. Therefore, for example, a method for calculating a yield of the whole device by using a product of yields of respective mask layers calculated by obtaining defect distributions in the respective mask layers, a method for decomposing a yield goal of the device into yields of respective processes and the like have been proposed (in, for example, Documents 1 and 2).

For example, according to a Poisson distribution model, a yield (hereinafter indicated by Y) is represented by the following formula:
Y=exp(−DD×A)
wherein DD indicates the number of defects per critical unit area and A indicates a critical area.

Specifically, after obtaining the number of defects DD of each principal masking process, namely, after obtaining the number of defects DD of each of a layer 1 (L1), a layer 2 (L2), etc. formed through the principal masking processes, a yield is calculated with respect to each principal masking process. Thereafter, a product of the calculated yields of the. respective masking processes is obtained, namely, a product of the calculated yields of the respective layers is obtained, and thus, a total yield of the whole fabrication process can be obtained. At this point, the layer 1 (L1), the layer 2 (L2), etc. respectively correspond to a masking process 1, a masking process 2, etc. In other words, when the total yield of the whole fabrication process is indicated by Ytotal and the yields calculated with respect to the layers are indicated by Y(L1), Y(L2), etc., the following formula stands:
Ytotal=Y(L1)×Y(L2)×etc.

Document 1: Lee Jacobson (National Semiconductor Corp.) et al., Development of Dynamic Tool PID/PWP Limits to Achieve Product Defect Density Goal, 1997 IEEE/SEMI Advanced Semiconductor Manufacturing Conference, pages 144-145

Document 2: Fred Lakhani (SEMATECH) et al., 0.25 ,μm Integrated Circuit Yield Model Design and Validation, ISSM 1997 San Francisco, Calif., October 1997

### SUMMARY OF THE INVENTION

However, in the method for calculating a yield described in Document 1 or 2, the total yield is expressed as a product of efficiency percentages (yields) of all the layers. Therefore, with respect to SRAMs (static random access memories) or DRAMs (dynamic random access memories), although a yield attained without providing redundancy repair can be calculated, a yield attained when the redundancy repair is provided cannot be calculated. Furthermore, as the capacity of each cell included in a memory cell array is increased, a larger difference in the yield is caused between the case where the redundancy repair is provided and the case where the redundancy repair is not provided. Specifically, in the conventional method for calculating a yield, a yield attained when the redundancy repair is provided cannot be predicated, and hence, although the actual yield is increased to, for example, 90% through the redundancy repair, there arises a problem that the yield is estimated as low as, for example, 70%.

As a countermeasure, Document 3 proposes a method for predicting a yield in consideration of redundancy repair with respect to each block of an integrated circuit device. According to this method, in the case where an integrated circuit device 10 includes a plurality of blocks 11 through 15, for example, as shown in FIG. 8, a yield is calculated in consideration of the redundancy repair with respect to each of the blocks 11 through 15, and a product of the yields of the blocks 11 through 15 thus calculated is obtained so as to calculate a yield of the whole integrated circuit device 10. However, since the yield is predicted with respect to each block in the method of Document 3, namely, since fraction defective is not calculated with respect to each layer, it is difficult to feedback the predicted yield to process development or to re-adjust the layout of layers on the basis of the predicted yield.

Document 3: Jitendra khare et al., Accurate Estimation of Defect-Related Yield Loss in Reconfigurable VLSI Circuits, IEEE JOURNAL OF SOLID-STATE CIRCUITS, VOL. 28, NO. 2, pages 146-156, February 1993

In consideration of the aforementioned conventional problems, an object of the invention is calculating a yield of a memory cell array provided with redundancy repair in consideration of fraction defective of each layer.

In order to achieve the object, the redundancy repaired yield calculation method of this invention for calculating a yield of a memory cell array provided with one or more redundancy repairs, includes a step of calculating the yield by using a product of a probability that failure-related defects in the number larger than the number of the redundancy repairs occur in one layer included in the memory cell array and a probability that no failure-related defect occurs in the other layer(s) included in the memory cell array.

Specifically, in the case where the number of the redundancy repairs is one and the memory cell array includes a first layer and a second layer, the yield may be calculated by obtaining a first product of a probability that one failure-related defect occurs in the first layer and a probability that no failure-related defect occurs in the second layer; obtaining a second product of a probability that one failure-related defect occurs in the second layer and a probability that no failure-related defect occurs in the first layer; and using a sum of the first product and the second product.

Alternatively, in the case where the number of the redundancy repairs is one and the memory cell array includes n (wherein n is an integer of 3 or more) layers, the yield may be calculated by obtaining products each of a probability that one failure-related defect occurs in an mth (wherein me is an arbitrary integer from 1 to n) layer and a probability that a failure-related defect occurs in none of layers other than the mth layer, the products being obtained with respect to respective cases where m is an integer from 1 to n, and using a sum of the products.

Alternatively, in the case where the number of the redundancy repairs is two and the memory cell array includes a first layer and a second layer, the yield may be calculated by obtaining a first product of a probability that two failure-related defects occur in the first layer and a probability that no failure-related defect occurs in the second layer; obtaining a second product of a probability that one failure-related defect occurs in the first layer and a probability that one failure-related defect occurs in the second layer; obtaining a third product of a probability that two failure-related defects occur in the second layer and a probability that no failure-related defect occurs in the first layer; and using a sum of the first product, the second product and the third product.

Alternatively, in the case where the number of the redundancy repairs is two and the memory cell array includes n (wherein n is an integer of 3 or more) layers, the yield may be calculated by obtaining first products each of a probability that two failure-related defects occur in an mth (wherein m is an arbitrary integer from 1 to n) layer and a probability that a failure-related defect occurs in none of layers other than the mth layer, the first products being obtained with respect to respective cases where m is an integer from 1 to n; obtaining second products each of a probability that one failure-related defect occurs in each of a pth (wherein p is an arbitrary integer from 1 to n) layer and a qth (wherein q is an arbitrary integer from 1 to n and is no equal to p) layer and a probability that a failure-related defect occurs in none of layers other than the pth and qth layers, the second products being obtained with respect to respective cases where p and q are integers of 1 to n; and using a sum of the first products and the second products.

Alternatively, in the case where the number of the redundancy repairs is s (wherein s is an integer of 3 or more) and the memory cell array includes a first layer and a second layer, the yield may be calculated by obtaining a first product of a probability that s failure-related defects occur in the first layer and a probability that no failure-related defect occurs in the second layer; obtaining a second product of a probability that (s-1) failure-related defects occur in the first layer and a probability that one failure-related defect occurs in the second layer; and using at least the first product and the second product.

Alternatively, in the case where the number of the redundancy repairs is s (wherein s is an integer of 3 or more) and the memory cell array includes n (wherein n is an integer of 3 or more) layers, the yield may be calculated by obtaining first products each of a probability that s failure-related defects occur in an mth (wherein m is an arbitrary integer from 1 to n) layer and a probability that a failure-related defect occurs in none of layers other than the mth layer, the first products being obtained with respect to respective cases where m is an integer from 1 to n; obtaining second products each of a probability that (s-1) failure-related defects occur in the mth layer and a probability that one failure-related defect occurs in one of layers other than the mth layer, the second products being obtained with respect to respective cases where m is an integer of 1 to n; and using at least the first products and the second products.

According to the redundancy repaired yield calculation method of this invention, a product of a probability that failure-related defects in the number equal to or smaller than the number of redundancy repairs occur in one layer and a probability that a failure-related defect occurs in none of the other layer(s) is used in the calculation of the yield. Therefore, a distribution probability of defects can be calculated in consideration of the number of defects that do not make a whole memory defective in accordance with the number of provided redundancy repairs, and hence, a yield attained by providing the redundancy repairs can be calculated. In other words, even in the case where an SRAM block or a DRAM block has a large scale, the yield of the whole memory can be precisely calculated.

In the redundancy repaired yield calculation method of this invention, the yield may be calculated separately in a case where the one or more redundancy repairs are provided as bit repair and in a case where the redundancy repairs are provided as word repair.

Also, in the redundancy repaired yield calculation method of this invention, the yield can be calculated with respect to each layer included in the memory cell array. Thus, the yield of each layer in consideration of the redundancy repairs can be calculated, and hence, the yield can be improved by changing the layout or the like of each layer.

It is an increment of the yield attained by providing the one or more redundancy repairs that is calculated in the redundancy repaired yield calculation method of this invention. Accordingly, when a yield attained without providing the one or more redundancy repairs is calculated by using a probability that a failure-related defect occurs in none of the layers included in the memory cell array and a sum of the thus obtained yield and the increment of the yield is obtained, the total yield of the whole memory cell array can be calculated.

Furthermore, since a relationship between the number of redundancy repairs provided to the memory cell array and the resultant yield can be easily predicted by the redundancy repaired yield calculation method of this invention, an appropriate number of redundancy repairs to be actually provided to the memory cell array can be determined on the basis of this relationship. In other words, since a yield can be predicted in consideration of redundancy repair before fabrication a product, the number of redundancy repairs to be prepared for the memory cell array can be previously determined.

As described so far, the present invention relates to the calculation method for a yield of a memory cell array and is particularly useful in application to a memory cell array provided with redundancy repair.

### BRIEF DESCRIPTION OF THE DRAWINGS

FIGS. 1A, 1B and 1C are diagrams for explaining a method for calculating a yield by using a Poisson distribution model employed in a redundancy repaired yield calculation method according to Embodiment 1 of the invention;

FIG. 2 is a cross-sectional view of a memory cell array to which the redundancy repaired yield calculation method of Embodiment 1 is applied;

FIG. 3 is a diagram for showing an example of the architecture of a redundancy repaired yield calculator according to Embodiment 1 of the invention;

FIG. 4 is a flowchart for the redundancy repaired yield calculation method of Embodiment 1 of the invention;

FIG. 5 is a table of yield calculation formulas used in accordance with the number of redundancy repairs in the redundancy repaired yield calculation method of Embodiment 1 of the invention;

FIG. 6 is a table for showing defect distributions of respective layers obtained in a redundancy repaired yield calculation method according to a modification of Embodiment 1 of the invention;

FIGS. 7A and 7B are diagrams for showing concepts of repair ratios employed in the redundancy repaired yield calculation methods of Embodiments 1 and 2 (including the modification) of the invention; and

FIG. 8 is a schematic cross-sectional view of an integrated circuit device to which a conventional yield prediction method is applied.

### DETAILED DESCRIPTION OF THE INVENTION

### EMBODIMENT 1

A redundancy repaired yield calculation method and a redundancy repaired yield calculator according to Embodiment 1 of the invention will now be described with reference to the accompanying drawings.

In this embodiment, a yield attained by providing a memory cell array of an SRAM or the like with redundancy repair is calculated, and for example, a Poisson distribution model is used in the calculation of the yield. Now, this embodiment will be described by exemplifying the use of a Poisson distribution model, but a negative binomial distribution model, a Γ distribution model or the like may be used instead of the Poisson distribution model.

According to the Poisson distribution model, a yield Y of a memory cell array is represented by the following formula:
Y=exp(−DD×A)
wherein A indicates an area (a critical area (in cm²)), and DD indicates the number of defects per unit area (more precisely, the number of defects per critical unit area (in /cm²)), which can be represented as follows:

$$DD = {\int }_{{x}_{min}}^{∞} DD ( x ) ⅆ x$$

wherein DD(x) indicates the number, per unit area, of defects with a size x, and xₘᵢₙ indicates the minimum dimension of a pattern of the memory cell array.

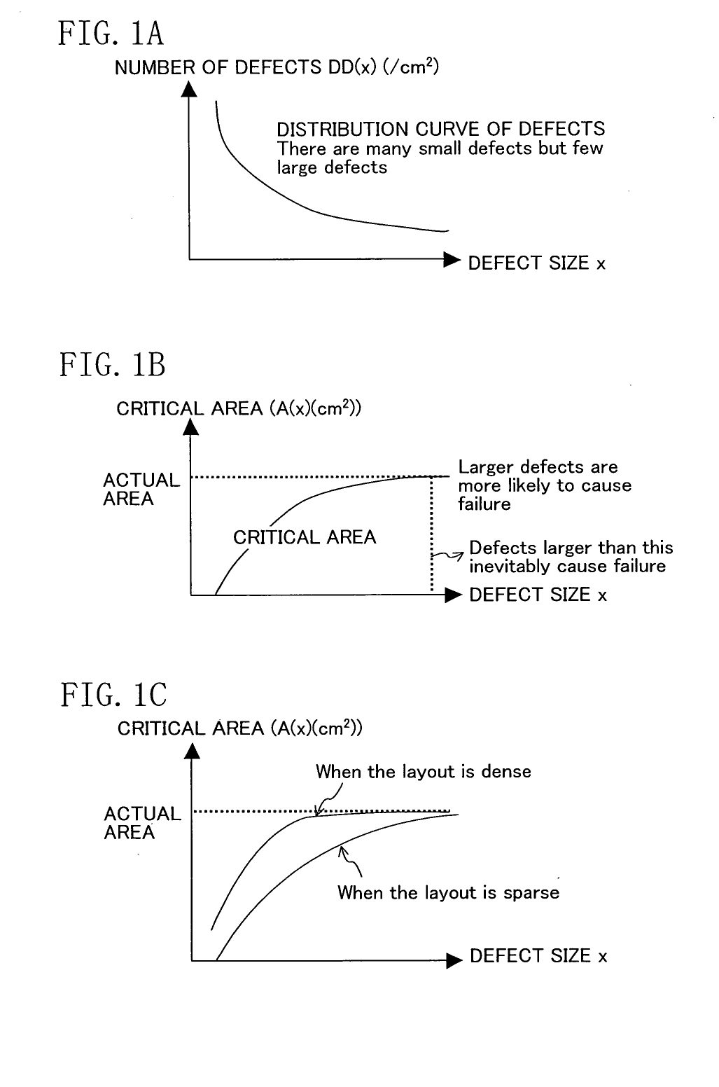

Now, a yield calculation method using the Poisson distribution model, the number of defects DD and the area A will be described with reference to graphs shown in FIGS. 1A through 1C.

FIG. 1A shows a defect distribution curve in which the abscissa indicates the size x of defects and the ordinate indicates the number of defects DD(x) (in/cm²). As shown in FIG. 1A, there are a small number of defects with large sizes but there are a large number of defects with small sizes. Herein, a defect. means, for example, a particle. In other words, when a particle falls on a portion between interconnects, a short-circuit is caused, and hence, the particle becomes a defect.

FIG. 1B shows dependency of a critical area A(x) on the size x of defects in which the abscissa indicates the size x of defects and the ordinate indicates the critical area A(x) (in cm²). Herein, the critical area A(x) means a critical area with respect to defects with the size x. As shown in FIG. 1B, as the size x of defects is larger, the critical area A(x) is larger. It is noted that a “critical area” means an “area of a portion that causes failure when a defect is present”. Accordingly, as the “critical area” is larger, a defect is more likely to be a defect that causes failure in the memory cell array (hereinafter referred to as the “failure-related defect”). In other words, as the size of a defect is larger, there is a higher possibility that the defect is a “failure-related defect”.

Furthermore, in the aforementioned calculation formula, Y=exp(−DD×A), “DD x A” can be represented as follows by using DD(x) and A(x):

$$DD \times A = {\int }_{{x}_{min}}^{∞} DD ( x ) \cdot A ( x ) ⅆ x$$

Specifically, the yield Y can be calculated by using the number of defects DD(x) shown in FIG. 1A and the critical area A(x) shown in FIG. 1B. Also, as shown in FIG. 1C, even when defects have the same size, the critical area is larger when the layout is dense than when the layout is sparse.

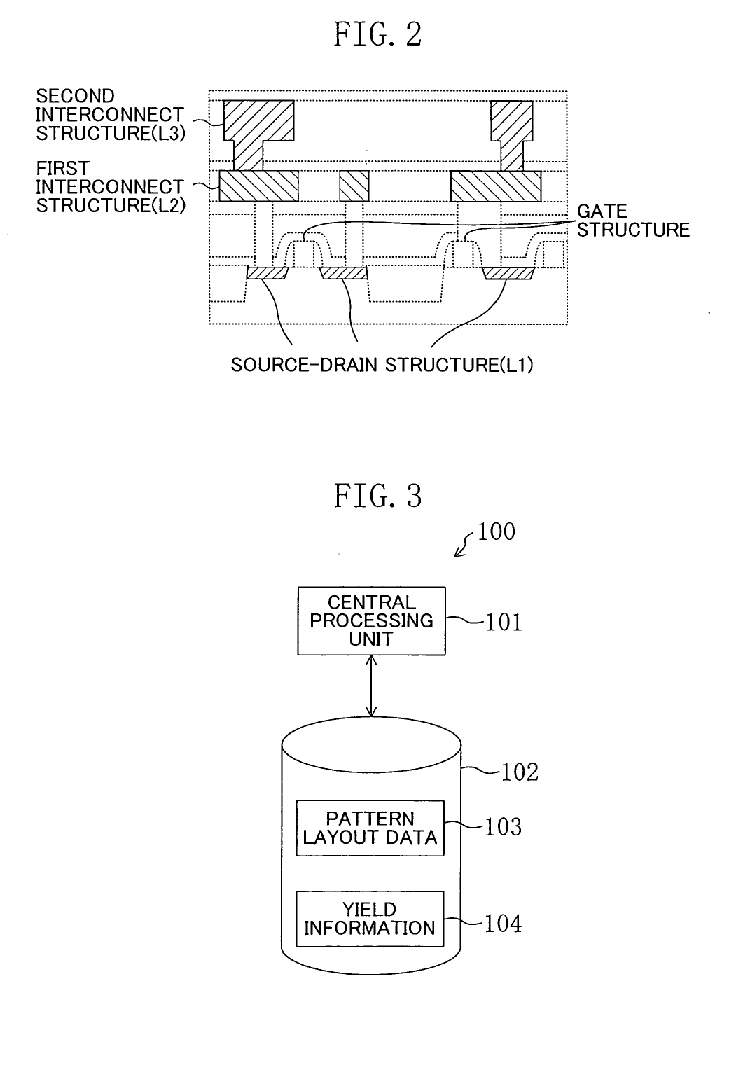

In this embodiment, a yield attained by providing redundancy repair is predicted on the basis of the yield calculation method using this Poisson distribution model. Now, for simplifying the explanation, a memory cell array having three layers L1, L2 and L3 formed by using three masks will be described as an example. In this case, the layers L1, L2 and L3 respectively correspond to a mask 1 (i.e., a mask for forming a source-drain structure), a mask 2 (i.e., a mask for forming a first interconnect structure) and a mask 3 (i.e., a mask for forming a second interconnect structure) used for fabricating a memory cell array having a cross-sectional structure, for example, shown in FIG. 2. Specifically, as shown in FIG. 2, the layer L1 is a layer of the source-drain structure of a transistor, the layer L2 is a layer of the first interconnect structure connected to the source-drain structure, and the layer L3 is a layer of the second interconnect structure connected to the first interconnect structure.

FIG. 3 shows an example of the architecture of a redundancy repaired yield calculator according to Embodiment 1 of the invention. As shown in FIG. 3, the calculator 100 of this embodiment includes a central processing unit (CPU) 101, and a storage 102 for storing pattern layout data 103 including pattern layouts of the layers L1, L2 and L3 and yield information 104. The CPU 101 reads, as operating means, the pattern layout data 103 from the storage 102, and executes the redundancy repaired yield calculation method of this embodiment described below by using the read pattern layout data 103. Also, as outputting means, the CPU 101 outputs, to the storage 102, the yield information 104 attained by providing the redundancy repair, which is obtained as a result of the execution of the redundancy repaired yield calculation method of this embodiment. The yield information 104 includes a yield Yn(Li) of each layer i (wherein i=1, 2 or 3) attained when the number of defects is ii, a yield Ym attained when the number of redundancy repairs is m; and a total yield Y.

Now, the redundancy repaired yield calculation method of this embodiment will be described in detail.

A yield Y(L1) of the layer L1 corresponding to the mask 1 is represented by the following fonmula according to the Poisson distribution model:
Y(L1)=exp(−DD(L1)×A(L1))
wherein A(L1) indicates a critical area of the layer L1 anld DD(L1) indicates the number of defects per unit area of the layer L1.

The number of defects DD(L1) is calculated by using, for example, data obtained in each masking process from a wafer pattemn defect inspection system

Also, tide critical area A(L1) is calculated by using the layout of the mask 1. Specifically, a critical area A is calculated on the basis of the density of an actual layout. When the layout is dense, the critical area A is large because even a small particle becomes a failure-related defect. On the other hand, when the layout is sparse, the critical area A is small because a rather larger particle does not become a failure-related defect.

In this manner. the yield Y(L1) of the layer L1 can be obtained. Similarly, the yields Y(L2) and Y(L3) of the layers L2 and L3 can be calculated as follows:
Y(L2)=exp(−DD(L2)×A(L2))
Y(L3)=exp(−DD(L3)×A(L3))

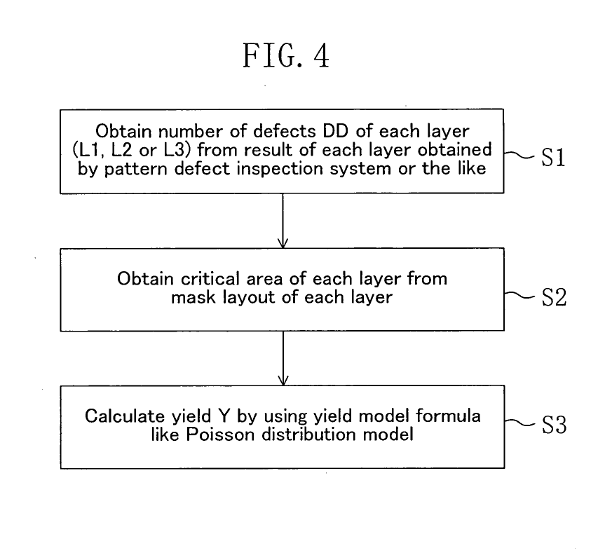

The number of defects DD and the critical area A are both fuinctiolls of each layer, and therefore, these values are different among the layers. Accordingly, the yield calculation method employed in the three-layer structure (including the layers L1, L2 and L3) can be expressed as a flowchart of FIG. 4.

Now, the yield calculation will be specifically described separately with respect to the case where the memory cell array is provided with no redundancy repair, the case where the memory cell array is provided with one redundancy repair, and the case where the memory cell array is provided with two redundancy repairs.

<Case of providing no redundancy repair>

First, a yield attained when the memory cell array is provided with no redundancy repair will be described. In this case, the number of failure-related defects in each of the layers L1, L2 and L3 should be zero. In other words, since there is no repair means, the memory cell array can be non-defective only when none of the layers has a defect.

In this case, the yield is equal to a probability that a defect occurs in none of the three layers, and hence, the yield Y0 attained without providing the redundancy repair is calculated as follows:

$$\begin{matrix}Y0 = Y0 ( L1 ) \times Y0 ( L2 ) \times Y0 ( L3 ) \\ = exp ( - DD ( L1 ) \times A ( L1 ) ) \times exp ( - DD ( L2 ) \times A ( L2 ) ) \times \\ exp ( - DD ( L3 ) \times A ( L3 ) )\end{matrix}$$

<Case of providing one redundancy repair>

Next, a yield attained by providing the memory cell array with one redundancy repair will be described by exemplifying the case where a bit line of a memory cell array included in a 32 kbit SRAM is provided with “one” redundancy repair. In this case, even when there is “one” failure-related defect, the memory cell array is not determined to be defective but is determined to be non-defective, and therefore, the yield is increased. In other words, even when one defect is caused in a bit line, the defect does not make the memory cell array defective but the memory cell array can be made “non-defective” by replacing this defective bit line with a redundancy bit line provided as the redundancy repair. As a result, the yield is increased.

At this point, in the calculation of the yield Y1 (corresponding to an increment) attained by providing one redundancy repair, it is considered that, in order that the memory cell array is prevented from being defective even when one defect is caused in, for example, the layer L1, the number of defects caused in the other layers L2 and L3 should be zero. In other words, since the number of redundancy repairs is one, the memory cell array cannot be “non-defective” when defects are caused in a plurality of bit lines.

Similarly, the following should be considered: In order that the memory cell array can be prevented from being defective even when the layer L2 has one defect, the number of defects caused in the other layers L1 and L3 should be zero; and in order that the memory cell array can be prevented from being defective even when the layer L3 has one defect, the number of defects caused in the other layers L1 and L2 should be zero.

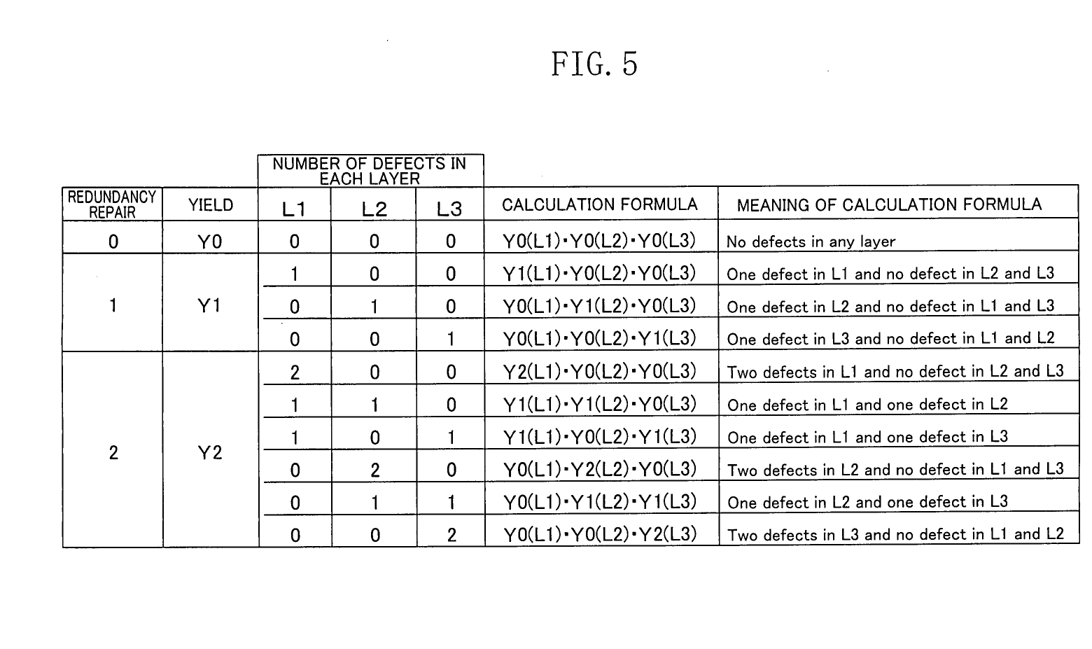

When the aforementioned conditions are taken into consideration, the yield Y1 attained by providing one redundancy repair is represented as shown in FIG. 5 and by the following formula:

$$\begin{matrix}Y1 = Y1 ( L1 ) \times [ probability that the number of defects in L2 and \\ L3 is zero ] + Y1 ( L2 ) \times [ probability that the number of \\ defects in L1 and L3 is zero ] + Y1 ( L3 ) \times [ probability that \\ the number of defects in L1 and L2 is zero ] \\ = Y1 ( L1 ) \times ( Y0 ( L2 ) \times Y0 ( L3 ) ) + Y1 ( L2 ) \times ( Y0 ( L1 ) \times Y0 ( L3 ) ) + \\ Y1 ( L3 ) \times ( Y0 ( L1 ) \times Y0 ( L2 ) )\end{matrix}$$

In this formula, for example, Y1(L1) indicates a probability that one defect occurs in the layer L1, and for example, (Y0(L2)×Y0(L3)) indicates a probability that the numbers of defects caused in the layers L2 and L3 are both zero.

In using the Poisson distribution model, a probability that n (wherein n is an integer) defects occur in a given layer is represented as follows:
Yn=((DD×A)ⁿ/n!)×exp(−DD×A)
Therefore, a probability that one defect occurs in a given layer is represented as follows:
Y1=(DD×A)×(exp(−DD×A))
Also, a probability that no defect occurs in a given layer is represented as follows:
Y0=exp(−DD×A)

The yield (the incremented yield) Y1 attained by providing the memory cell array with one redundancy repair can be obtained in the aforementioned manner. Accordingly, in this case, the total yield Y is calculated as follows:
Y=Y0+Y1

<Case of providing two redundancy repairs>

Next, a yield Y2 attained when the memory cell array is provided with two redundancy repairs will be described. In this case, the allowable number of failure-related defects is two, and when the number of defects is larger than two, the memory cell array cannot be made non-defective through the redundancy repair. Therefore, in consideration of a probability that two or less failure-related defects are distributed in the layers L1 through L3, the yield Y2 (corresponding to an increment) attained when two redundancy repairs are provided is expressed as shown in FIG. 5.

As shown in FIG. 5, when “two” redundancy repairs are provided, the memory cell array is not defective if two defects occur in one of the layers L1 through L3. Also, if the two defects are respectively dispersed in two of the layers L1 through L3, the memory cell array is not defective. In other words, the memory cell array is not defective in the case where each of the layers L1 and L2 has one defect and the layer L3 has no defect, in the case where each of the layers L1 and L3 has one defect and the layer L2 has no defect, or in the case where each of the layers L2 and L3 has one defect and the layer L1 has no defect.

The calculated probabilities of these cases are expressed as shown in FIG. 5 and as follows:

[Probability that two defects occur in L1 and no defect occurs in L2 and L3]
=Y2(L1)×Y0(L2)×Y0(L3)

[Probability that one defect occurs in each of L1 and L2 and no defect occurs in L3]
=Y1(L1)×Y1(L2)×Y0(L3)

[Probability that one defect occurs in each of L1 and L3 and no defect occurs in L2]
=Y1(L1)×Y0(L2)×Y1(L3)

[Probability that two defects occur in L2 and no defect occurs in L1 and L3]
=Y0(L1)×Y2(L2)×Y0(L3)

[Probability that one defect occurs in each of L2 and L3 and no defect occurs in L1]
=Y0(L1)×Y1(L2)×Y1(L3)

[Probability that two defects occur in L3 and no defect occurs in L1 and L2]
=Y0(L1)×Y0(L2)×Y2(L3)

At this point, for example, Y0(Li) is a probability that no defect occurs in the layer L1 and is represented as follows:

Y0(L1)=exp(−DD(L1)×A(L1))

For example, Y1(L1) is a probability that one defect occurs in the layer L1 and is represented as follows:
Y1(L1)=(DD(L1)×A(L1))×(exp(−DD(L1)×A(L1)))
Also, for example Y2(L1) is a probability that two defects occur in the layer L1 and is represented as follows:
Y2(L1)=((DD(L1)×A(L1))²/2)×(exp(−DD(L1)×A(L1)))

The yield (the incremented yield) Y2 attained when the memory cell array is provided with two redundancy repairs is calculated by using the probabilities calculated in the aforementioned manner as follows:

$$\begin{matrix}Y2 = Y2 ( L1 ) \times Y0 ( L2 ) \times Y0 ( L3 ) + Y1 ( L1 ) \times Y1 ( L2 ) \times Y0 ( L3 ) + \\ Y1 ( L1 ) \times Y0 ( L2 ) \times Y1 ( L3 ) + Y0 ( L1 ) \times Y2 ( L2 ) \times Y0 ( L3 ) + \\ Y0 ( L1 ) \times Y1 ( L2 ) \times Y1 ( L3 ) + Y0 ( L1 ) \times Y0 ( L2 ) \times Y2 ( L3 )\end{matrix}$$

Accordingly, in this case, the total yield Y is calculated as follows:
Y=Y0+Y1+Y2

As described so far, according to Embodiment 1, a product of a probability that failure-related defects in the number smaller than the number of provided redundancy repairs occur in a given layer and a probability that no failure-related defect occurs in the other layers is used in the yield calculation. Therefore, in consideration of the number of defects that do not make the whole memory defective in accordance with the set number of redundancy repairs, the distribution probability of defects can be calculated, and hence, a yield attained when the redundancy repairs are provided can be calculated. In other words, a yield of the products can be precisely calculated even when each SRAM block has a large scale.

Also, according to Embodiment 1, the relationship between the number of redundancy repairs to be provided to the memory cell array and the resultant yield can be easily predicted, and therefore, an appropriate number of redundancy repairs to be actually provided to the memory cell array can be determined on the basis of the relationship. In other words, the yield can be predicted in consideration of the redundancy repairs before fabrication of the products, and therefore, the number of redundancy repairs to be prepared for the memory cell array can be previously determined.

Although the memory cell array includes the three layers (namely, three masks are used in fabricating the memory cell array) in Embodiment 1 described above, the concept of this embodiment is similarly applied to the case where the memory cell array includes layers in the number other than three. For example, in the case where one redundancy repair is provided and the memory cell array includes two layers, a yield may be calculated as follows: A first product of a probability that one failure-related defect occurs in a first layer and a probability that no failure-related defect occurs in a second layer is obtained, a second product of a probability that one failure-related defect occurs in the second layer and a probability that no failure-related defect occurs in the first layer is obtained, and a sum of the first product and the second product may be used for calculating the yield. Alternatively, when two redundancy repairs are provided and the memory cell array includes two layers, a yield may be calculated as follows: A first product of a probability that two failure-related defects occur in a first layer and a probability that no failure-related defect occurs in a second layer is obtained, a second product of a probability that one failure-related defect occurs in the first layer and a probability that one failure-related defect occurs in the second layer is obtained, a third product of a probability that two failure-related defects occur in the second layer and a probability that no failure-related defect occurs in the first layer is obtained, and a sum of the first product, the second product and the third product may be used for calculating the yield.

Furthermore, although the number of redundancy repairs is one or two in Embodiment 1 described above, it goes without saying that the number of redundancy repairs may be three or more. However, when the number of redundancy repairs is too large, the area of the memory cell array becomes disadvantageously large, and therefore, it is not preferred that the number of redundancy repairs is unlimitedly large.

Moreover, although the memory cell array is included in the SRAM in Embodiment 1, it goes without saying that the memory cell array may be included in another memory such as a DRAM.

Also, although the redundancy repair is provided as a redundancy bit line in Embodiment 1, it goes without saying that the redundancy repair may be provided as a redundancy word line. Specifically, a yield may be calculated separately in the case where the redundancy repair is provided as bit repair and the case where it is provided as word repair.

Moreover, although Embodiment 1 is described for simplification in assuming that a cell or a fuse used for the redundancy repair has a yield of 100%, calculation formulas for such a yield may be created on the assumption of actual use, so as to be used in the redundancy repaired yield calculation method of this invention.

### MODIFICATION OF EMBODIMENT 1

A redundancy repaired yield calculation method according to a modification of Embodiment 1 of the invention will now be described. This modification is different from Embodiment 1 as follows: While the number of redundancy repairs is one or two in Embodiment 1, three or more redundancy repairs are provided in this modification. It goes without saying that a redundancy repaired yield calculator similar to that of Embodiment 1 shown in FIG. 3 can be used in the redundancy repaired yield calculation method of this modification.

Assuming that the number of layers of a memory cell array is n (wherein n is an integer of two or more), a yield Y₁ of one layer (hereinafter referred to as the layer 1) is represented by the following formula:

$$\begin{matrix}{Y}_{1} = [ probability that the layer 1 is non \text{-} defective ] \\ ( corresponding to the case where no redundancy repair is \\ provided ) + [ probability that one defect occurs in the layer \\ 1 ] \times [ probability that the other layers are non \text{-} defective ] \\ ( corresponding to the case where one redundancy repair \\ is provided ) + [ probability that two defects occur in the \\ layer 1 ] \times [ probability that the other layers are \\ non \text{-} defective ] + \{ probability that one defect occurs in \\ each of the layer 1 and another layer ] \times [ probability \\ that the other layers are non \text{-} defective ] \} / 2 \\ ( corresponding to the case where two redundancy repairs \\ are provided ) + etc . \\ = exp ( - {D}_{01} \cdot {A}_{c1} ) + ( {D}_{01} \cdot {A}_{c1} ) \cdot exp ( - {D}_{01} \cdot {A}_{c1} ) \cdot {\prod }_{i = 2}^{n} ( exp ( - {D}_{0 i} \cdot \\ {A}_{ci} ) ) + {( {D}_{01} \cdot {A}_{c1} )}^{2} \cdot ( 1 / 2 ) \cdot exp ( - {D}_{01} \cdot {A}_{c1} ) \cdot {\prod }_{i = 2}^{n} ( exp ( - {D}_{0 i} \cdot \\ {A}_{ci} ) ) + \{ ( {D}_{01} \cdot {A}_{c1} ) \cdot exp ( - {D}_{01} \cdot {A}_{c1} ) \cdot {\sum }_{i = 2}^{n} [ ( {D}_{0 i} \cdot {A}_{ci} ) \cdot exp ( - {D}_{0 i} \cdot \\ {A}_{ci} ) \cdot exp ( - {D}_{0 i} \cdot {A}_{ci} ) \cdot ( {\prod }_{j = 2}^{n} exp ( - {D}_{0 j} \cdot {A}_{cj} ) ) / \\ exp ( - {D}_{0 i} \cdot {A}_{ci} ) ] \} / 2 + etc .\end{matrix}$$

In the aforementioned formula, D₀₁ indicates the number of defects per unit area of the layer 1, A_{c1} indicates a critical area of the layer 1, D₀ᵢ indicates the number of defects per unit area of the ith layer (hereinafter referred to as the layer i), A_{ci} indicates a critical area of the layer i, D₀ⱼ indicates the number of defects per unit area of the jth layer (hereinafter referred to as the layer j), and A_{cj} indicates a critical area of the layer j.

Specifically, assuming that the number of redundancy repairs is three, in the calculation of the yield of the layer 1 (designated as the relevant layer below), it is necessary to consider the following in addition to the fraction defective (attained when the number of redundancy repairs is 0 through 2) considered in Embodiment 1:

[probability that three defects occur in the relevant layer]×[probability that the other layers are non-defective]+[probability that two defects occur in the relevant layer]×[probability that one defect occurs in another layer and the other layers are non-defective]×+[probability that one defect occurs in the relevant layer]×[probability that two defects occur in another layer and the other layers are non-defective]+[probability that one defect occurs in the relevant layer]×[probability that one defect occurs in each of other two layers and the other layers are non-defective]

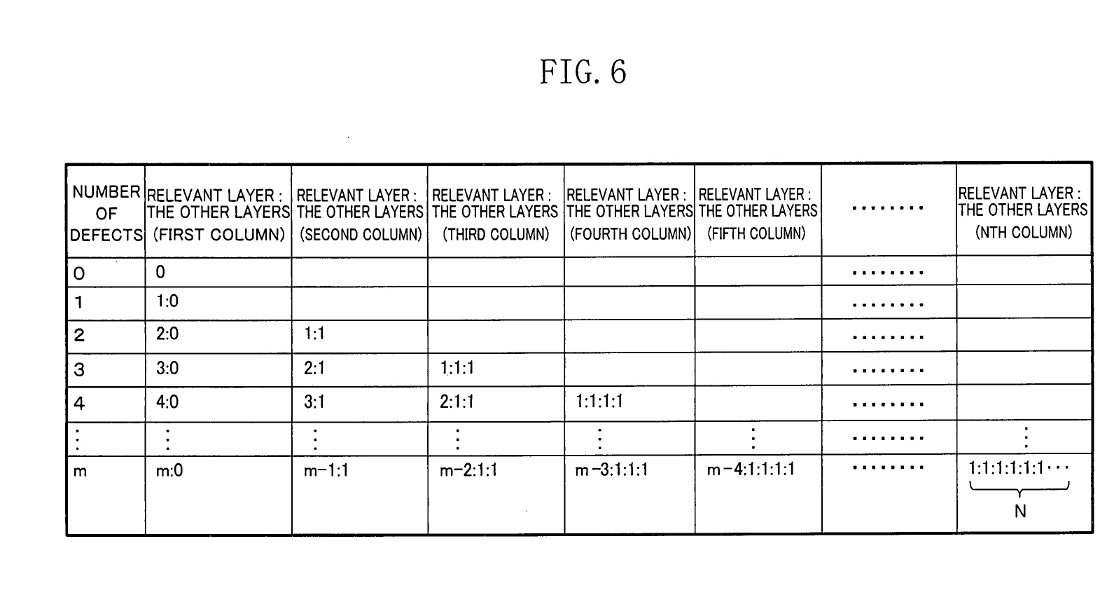

At this point, for simplifying the yield calculation method, it may be assumed that merely one defect (precisely, a failure-related defect) occurs in the layers other than the relevant layer (in other words, the third item of the aforementioned formula may not be considered). On this assumption, the defect distribution states of the respective layers obtained when the number of layers is n and the number of redundancy repairs is m (wherein m is an integer smaller than n) can be expressed as shown in FIG. 6. The number of defect distribution states, namely, the number of kinds of the redundancy repair conditions, may be limitlessly increased as far as the calculation goes, but actually, although it depends upon the scale of the memory cell array, it is efficiently assumed in most cases that merely one defect occurs in the layers other than the relevant layer.

Also, the yield of the layer 1 is a sum of the probabilities obtained with respect to all the redundancy repair conditions shown in FIG. 6. However, the probability obtained with respect to the uppermost row in each column of FIG. 6 should be divided by the number of layers that have defects. In other words, when the yield of the layer 1 is indicated as Y₁, the following formula stands:

$$\begin{matrix}{Y}_{1} = ( sum of probabilities of the first column ) + ( probability \\ of the uppermost row in the second column ) / 2 + \\ ( probability of the uppermost row in the third column ) / 3 + \\ … + ( probability of the uppermost row in the Nth column ) / \\ N + ( sum of probabilites of the other rows in the second \\ column ) + ( sum of probabilities of the other rows in the \\ third column ) + … + ( sum of probabilities of the other \\ rows in the Nth column )\end{matrix}$$

Furthermore, a “sum of the probabilities with respect to the redundancy repair condition of the first column” can be represented as follows:

$$exp ( - {D}_{01} \cdot {A}_{c1} ) + exp ( - {D}_{01} \cdot {A}_{c1} ) \cdot \{ {\sum }_{k = 1}^{m} {( {D}_{01} \cdot {A}_{c1} )}^{k} / k ! \cdot {\prod }_{i = 2}^{n} exp ( - {D}_{01} \cdot {A}_{ci} ) \}$$

Also, a “sum of the probabilities with respect to the redundancy repair condition of the second column” can be represented as follows:

$$\{ ( {D}_{01} \cdot {A}_{c1} ) \cdot exp ( - {D}_{01} \cdot {A}_{c1} ) \cdot {\sum }_{l = 2}^{n} [ {D}_{0 l} \cdot {A}_{cl} \cdot exp ( - {D}_{0 l} \cdot {A}_{cl} ) \cdot ( {\prod }_{i = 2}^{m} exp ( - {D}_{0 i} \cdot {A}_{ci} ) ) / exp ( - {D}_{0 l} \cdot {A}_{cl} ) ] \} / 2 + \{ exp ( - {D}_{01} \cdot {A}_{c1} ) \cdot {\sum }_{k = 2}^{m - 1} {( {D}_{01} \cdot {A}_{c1} )}^{k} / k ! \} \cdot {\sum }_{l = 2}^{n} \{ {D}_{0 l} \cdot {A}_{cl} \cdot exp ( - {D}_{0 l} \cdot {A}_{cl} ) \cdot ( {\prod }_{i = 2}^{n} exp ( - {D}_{0 i} \cdot {A}_{ci} ) ) / exp ( - {D}_{0 l} \cdot {A}_{cl} ) \}$$

Furthermore, a “sum of probabilities with respect to the redundancy repair condition of the third column” can be represented as follows:

$$\{ ( {D}_{01} \cdot {A}_{c1} ) \cdot exp ( - {D}_{01} \cdot {A}_{c1} ) \cdot {\sum }_{{lj = 2}_{( l \neq j )}}^{n} [ {D}_{0 l} \cdot {A}_{cl} \cdot exp ( - {D}_{0 l} \cdot {A}_{cl} ) \cdot {D}_{0 j} \cdot {A}_{cj} \cdot exp ( - {D}_{0 j} \cdot {A}_{cj} ) \cdot ( {\prod }_{i = 2}^{n} exp ( - {D}_{0 i} \cdot {A}_{ci} ) ) / ( - exp ( {D}_{0 l} \cdot {A}_{cl} ) \cdot exp ( - {D}_{0 j} \cdot {A}_{cj} ) ) ] \} / 3 + \{ exp ( - {D}_{01} \cdot {A}_{c1} ) \cdot {\sum }_{k = 2}^{m - 2} {( {D}_{01} \cdot {A}_{c1} )}^{k} / k ! \} \cdot {\sum }_{{lj = 2}_{( l \neq j )}}^{n} [ ( {D}_{0 l} \cdot {A}_{cl} ) \cdot exp ( - {D}_{0 l} \cdot {A}_{cl} ) \cdot ( {D}_{0 j} \cdot {A}_{cj} ) \cdot exp ( - {D}_{0 j} \cdot {A}_{cj} ) \cdot ( {\prod }_{i = 2}^{n} exp ( - {D}_{0 i} \cdot {A}_{ci} ) ) / exp ( - {D}_{0 l} \cdot {A}_{cl} ) \cdot exp ( - {D}_{0 j} \cdot {A}_{cj} ) ) ]$$

Moreover, a “sum of probabilities with respect to the redundancy repair condition of the Nth column” can be represented as follows:

$$\{ ( {D}_{01} \cdot {A}_{c1} ) \cdot exp ( - {D}_{01} \cdot {A}_{c1} ) \cdot {\sum }_{{j1 , j2 , … jn = 2}_{( j1 \neq j2 \neq … \neq jn )}}^{n} { \overbrace{[ ( {D}_{0 j1} \cdot {A}_{cj1} ) \cdot exp ( - {D}_{0 j1} \cdot {A}_{cj1} ) \cdot ( {D}_{0 j2} \cdot {A}_{cj2} ) \cdot exp ( - {D}_{0 j2} \cdot {A}_{cj2} ) …}}^{N} \cdot ( {\prod }_{i = 2}^{n} ( ( exp ( - {D}_{0 i} \cdot {A}_{ci} ) ) / {\underbrace{( exp ( - {D}_{0 j1} \cdot {A}_{cj1} ) \cdot exp ( - {D}_{0 j2} \cdot {A}_{cj2} ) … ) ) ] \} / n}}_{N} + ( exp ( - {D}_{01} \cdot {A}_{c1} ) \cdot ( {\sum }_{k = 1}^{m - ( N - 1 )} {( {D}_{01} \cdot {A}_{c1} )}^{k} / k ! ) \cdot {\sum }_{{j1 , j2 , … jn = 2}_{( j1 \neq j2 \neq … \neq jn )}}^{n} { \overbrace{[ ( {D}_{0 j1} \cdot {A}_{cj1} ) \cdot exp ( - {D}_{0 j1} \cdot {A}_{cj1} ) \cdot exp ( - {D}_{0 j2} \cdot {A}_{cj2} ) \cdot exp ( - {D}_{0 j2} \cdot {A}_{0 j2} ) …}}^{N} \cdot ( {\prod }_{i = 2}^{n} ( ( exp ( - {D}_{0 i} \cdot {A}_{ci} ) ) / {\underbrace{( exp ( - {D}_{0 j1} \cdot {A}_{cj1} ) \cdot exp ( - {D}_{0 j2} \cdot {A}_{cj2} ) … ) ) ]}}_{N}$$

In the aforementioned formulas, D₀₁ indicates the number of defects per unit area of the layer 1, A_{cl} indicates a critical area of the layer 1, D₀ᵢ indicates the number of defects per unit area of the layer i, A_{ci} indicates a critical area of the layer i, D₀₁ indicates the number of defects per unit area of a layer 1, A_{c1} indicates a critical area of the layer 1, D₀ⱼ indicates the number of defects per unit area of a layer j, A_{cj} indicates a critical area of the layer j, D₀ⱼᵢ indicates the number of defects per unit area of a layer j1, A_{cj1} indicates a critical area of the layer j1, D₀ⱼ₂ indicates the number of defects per unit area of a layer j2, and A_{cj2} indicates a critical area of the layer j2.

Specifically, according to this modification, in the case where the number of redundancy repairs is m (wherein m is an integer of 3 or more) and the memory cell array includes a layer 1 and a layer 2 (namely, the number of layers is two), a first product of a probability that m failure-related defects occur in the layer 1 and a probability that no failure-related defect occurs in the layer 2 is obtained, and a second product of a probability that m-1 failure-related defects occur in the layer 1 and a probability that one failure-related defect occurs in the layer 2 is obtained, and at least the first product and the second product are used for calculating a yield.

Also, in this modification, in the case where the number of redundancy repairs is m (wherein m is an integer of 3 or more) and the memory cell array includes n (wherein n is an integer larger than 3) layers, a first product of a probability that m failure-related defects occur in the ith (wherein i is an arbitrary integer from 1 to n) layer and a probability that no failure-related defect occurs in layers other than the layer i, a second product of a probability that m-1 failure-related defects occur in the layer i and a probability that one failure-related defect occurs in one of layers other than the layer i, a third product of a probability that m-2 failure-related defects occur in the layer i and a probability that one failure-related defect occurs in each of two layers other than the layer i, . . . , and an Nth product of a probability that one failure-related defect occurs in the layer i and a probability that one failure-related defect occurs in each of m-1 layers other than the layer i are respectively obtained, and at least the first through the Nth products are used for calculating a yield.

According to this modification, the same effect as that attained in Embodiment 1 can be attained.

### EMBODIMENT 2

A redundancy repaired yield calculation method according to Embodiment 2 of the invention will now be described. This embodiment is different from Embodiment 1 as follows: While the yield of the whole memory cell array is calculated in Embodiment 1, a yield of each layer included in the memory cell array is calculated in this embodiment. It goes without saying that a redundancy repaired yield calculator similar to that of Embodiment 1 shown in FIG. 3 can be used in the redundancy repaired yield calculation method of this embodiment.

Specifically, a yield Y(L1) of a layer L1 included in a three-layer structure (having layers L1, L2 and L3) similar to that described Embodiment 1 can be calculated by the following formula:
Y(L1)=[probability that no failure-related defect occurs in L1]+[probability that a failure-related defect occurs in L1 alone]

At this point, in consideration of yields Y0, Y1 and Y2 shown in FIG. 5, the yield Y(L1) is expressed as follows:
Y(L1)=Y0(L1)+Y1(L1)×Y0(L2)×Y0(L3)+Y2(L1)×Y0(L2)×Y0(L3)+(Y1(L1)×Y1(L2)×Y0(L3)+Y1(L1)×Y0(L2)×Y1(L3))/2

Specifically, in this formula, a yield attained without providing redundancy repair is indicated by Y0(L1). Also, a yield (corresponding to an increment) attained by providing one redundancy repair is indicated by Y1(L1)×Y0(L2)×Y0(L3) in consideration of a probability that the layer L1 alone is provided with the redundancy repair to be non-defective, namely, in consideration of a probability that one defect occurs in the layer L1 alone (namely, no defect occurs in the layers other than the layer L1). Furthermore, a yield (corresponding to an increment) attained by providing two redundancy repairs is indicated by Y2(L1)×Y0(L2)×Y0(L3)+(Y1(L1)×Y1(L2)×Y0(L3)+Y1(L1)×Y0(L2)×Y1(L3))/2 in consideration of a probability that the layer L1 is provided with the redundancy repairs to be non-defective, and more specifically, in consideration of a probability that two defects occur in the layer L1 alone and a probability that one defect occurs in the layer L1 and one defect occurs in another layer other than the layer L1. At this point, the probability that two defects occur in the layer L1 alone is indicated by Y2(L1)×Y0(L2)×Y0(L3). Also, the probability that one defect occurs in the layer L1 and one defect occurs in another layer corresponds to a sum of a probability that one defect occurs in the layer L1 and one defect occurs in the layer L2 and a probability that one defect occurs in the layer L1 and one defect occurs in the layer L3, and hence is indicated by (Y1(L1)×Y1(L2)×Y0(L3)+Y1(L1)×Y0(L2)×Y1(L3))/2. However, this case includes a case where one defect occurs in the layer L2 and one defect occurs in the layer L1 (which case makes a contribution to the yield of the layer L2) and a case where one defect occurs in the layer L3 and one defect occurs in the layer L1 (which case makes a contribution to the yield of the layer L3), and therefore, the sum is divided by two.

Also, the yield Y(L2) or Y(L3) of the layer L2 or L3 can be calculated in the same manner as the yield Y(L1).

According to Embodiment 2, instead of the yield of the whole memory cell array provided with the redundancy repair, the yield of a specific layer can be calculated in consideration of the redundancy repair. Therefore, the yield of each layer can be improved by adjusting the layout or the like of the layer.

Although the number of redundancy repairs is one or two in the description of Embodiment 2, it goes without saying that the number of redundancy repairs can be three or more as in the modification of Embodiment 1. However, when the number of redundancy repairs is too large, the area of the memory cell array becomes disadvantageously large. Therefore, it is not preferred that the number of redundancy repairs is limitlessly increased.

Also, in Embodiment 1, the modification thereof or Embodiment 2, in the calculation of a probability that at least one defect occurs in at least one layer (for example, the calculation of the probability that two defects occur in the layer L1 alone, namely, calculation of Y2(L1)×Y0(L2)×Y0(L3), described in this embodiment), the accuracy of the yield calculation can be further improved by multiplying the calculated probability by a given repair ratio. Now, the repair ratio will be described with reference to the accompanying drawings.

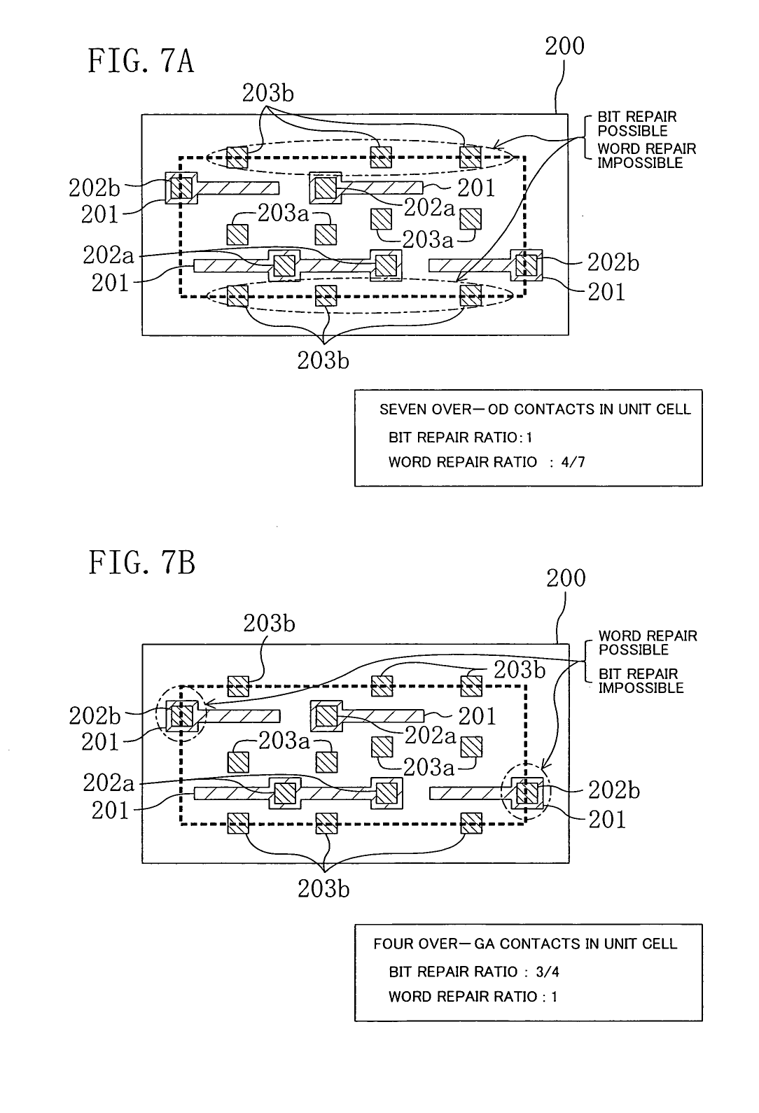

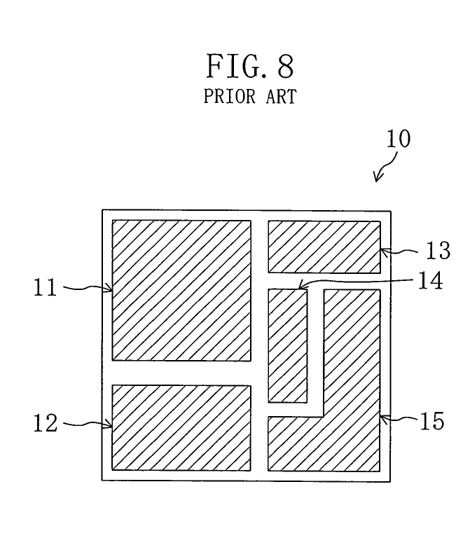

FIGS. 7A and 7B are diagrams for showing concept of a bit repair ratio and a word repair ratio employed in the cases where the redundancy repair is provided as a redundancy bit line and a redundancy word line, respectively. In each of FIGS. 7A and 7B, a unit cell region is surrounded with a broken line. Also, in each of FIGS. 7A and 7B, the longitudinal direction of the drawing corresponds to a bit line direction and the lateral direction of the drawing corresponds to a word line direction.

As shown in each of FIGS. 7A and 7B, a plurality of gate electrodes (GA) 201 are formed on a semiconductor substrate 200 and contacts (over-GA contacts) 202a and 202b are formed on the respective gate electrodes 201. In this case, each of the (three) over-GA contacts 202a is present within the unit cell region as a whole. On the other hand, merely a half of each of the (two) over-GA contacts 202b is present within the unit cell region. In other words, merely a half of each over-GA contact 202b is present within the unit cell region. Therefore, the total number of over-GA contacts 202a and 202b present within the unit cell region is four.

Also, as shown in each of FIGS. 7A and 7B, an impurity diffusion layer (OD) is fonned on the semiconductor substrate 200, and contacts (over-OD contacts) 203a and 203b are formed on the impurity difflusion layer. In this case, each of the (four) over-OD contacts 203a is present within the unit cell region as a whole. On the other hand, merely a half of each of (six) over-OD contacts 203b is present within the unit cell region. In other words, merely a half of each over-OD contact 203b is present within the unit cell region. Therefore, the total number of over-OD contacts 203a and 203b present within the unit cell region is seven.

As shown in FIG. 7A, in the case where the over-OD contacts 203a and 203b are provided within the unit cell region in the number of seven in total and it is possible to perform bit repair but impossible to perform word repair, both the over-OD contacts 203a and 203b can be subjected to the bit repair, and hence, the total number of contacts that can be repaired through the bit repair is seven. Accordingly, the bit repair ratio is one. On the other hand, in the case where it is impossible to perform the bit repair but possible to perform the word repair, the over-OD contacts 203b cannot be subjected to the word repair as shown in FIG. 7A, namely, the over-OD contacts 203a alone can be subjected to the word repair, and hence, the number of contacts that can be repaired through the word repair is four. Accordingly, the word repair ratio is 4/7.

Alternatively, as shown in FIG. 7B, in the case where the over-GA contacts 202a and 202b are provided within the unit cell region in the number of four in total and it is possible to perform the bit repair but impossible to perform the word repair, since the over-GA contacts 202b cannot be subjected to the bit repair, namely, the over-GA contacts 202a alone can be subjected to the bit repair, the total number of contacts that can be repaired through the bit repair is three. Accordingly, the bit repair ratio is 3/4. On the other hand, in the case where it is impossible to perform the bit repair but possible to perform the word repair, since the both over-GA contacts 202a and 202b can be subjected to the word repair, the total number of contacts that can be repaired through the word repair is four. Accordingly, the word repair ratio is one.

1. A redundancy repaired yield calculation method for calculating a yield of a memory cell array provided with one or more redundancy repairs, comprising a step of:
calculating said yield by using a product of a probability that failure-related defects in the number equal to or smaller than the number of said redundancy repairs occur in one layer included in said memory cell array and a probability that no failure-related defect occurs in the other layer(s) included in said memory cell array.

2. The redundancy repaired yield calculation method of claim 1,
wherein the number of said redundancy repairs is one,
said memory cell array includes a first layer and a second layer, and
said yield is calculated by:
obtaining a first product of a probability that one failure-related defect occurs in said first layer and a probability that no failure-related defect occurs in said second layer;
obtaining a second product of a probability that one failure-related defect occurs in said second layer and a probability that no failure-related defect occurs in said first layer; and
using a sum of said first product and said second product.

3. The redundancy repaired yield calculation method of claim 1,
wherein the number of said redundancy repairs is one,
said memory cell array includes n (wherein n is an integer of 3 or more) layers, and
said yield is calculated by obtaining products each of a probability that one failure-related defect occurs in an mth (wherein m is an arbitrary integer from 1 to n) layer and a probability that a failure-related defect occurs in none of layers other than said mth layer, said products being obtained with respect to respective cases where m is an integer from 1 to n, and using a sum of said products.

4. The redundancy repairs yield calculation method of claim 1,
wherein the number of said redundancy repairs is two,
said memory cell array includes a first layer and a second layer, and
said yield is calculated by:
obtaining a first product of a probability that two failure-related defects occur in said first layer and a probability that no failure-related defect occurs in said second layer;
obtaining a second product of a probability that one failure-related defect occurs in said first layer and a probability that one failure-related defect occurs in said second layer;
obtaining a third product of a probability that two failure-related defects occur in said second layer and a probability that no failure-related defect occurs in said first layer; and
using a sum of said first product, said second product and said third product.

5. The redundancy repaired yield calculation method of claim 1,
wherein the number of said redundancy repairs is two,
said memory cell array includes n (wherein n is an integer of 3 or more) layers, and
said yield is calculated by:
obtaining first products each of a probability that two failure-related defects occur in an mth (wherein m is an arbitrary integer from 1 to n) layer and a probability that a failure-related defect occurs in none of layers other than said mth layer, said first products being obtained with respect to respective cases where m is an integer from 1 to n;
obtaining second products each of a probability that one failure-related defect occurs in each of a pth (wherein p is an arbitrary integer from 1 to n) layer and a qth (wherein q is an arbitrary integer from 1 to n and is no equal to p) layer and a probability that a failure-related defect occurs in none of layers other than said pth and qth layers, said second products being obtained with respect to respective cases where p and q are integers of 1 to n; and
using a sum of said first products and said second products.

6. The redundancy repaired yield calculation method of claim 1,
wherein the number of said redundancy repairs is s (wherein s is an integer of 3 or more),
said memory cell array includes a first layer and a second layer, and
said yield is calculated by:
obtaining a first product of a probability that s failure-related defects occur in said first layer and a probability that no failure-related defect occurs in said second layer;
obtaining a second product of a probability that (s-1) failure-related defects occur in said first layer and a probability that one failure-related defect occurs in said second layer; and
using at least said first product and said second product.

7. The redundancy repaired yield calculation method of claim 1,
wherein the number of said redundancy repairs is s (wherein s is an integer of 3 or more),
said memory cell array includes n (wherein n is an integer of 3 or more) layers, and
said yield is calculated by:
obtaining first products each of a probability that s failure-related defects occur in an mth (wherein m is an arbitrary integer from 1 to n) layer and a probability that a failure-related defect occurs in none of layers other than said mth layer, said first products being obtained with respect to respective cases where m is an integer from 1 to n;
obtaining second products each of a probability that (s-1) failure-related defects occur in said mth layer and a probability that one failure-related defect occurs in one of layers. other than said mth layer, said second products being obtained with respect to respective cases where m is an integer of 1 to n; and
using at least said first products and said second products.

8. The redundancy repaired yield calculation method of claim 1,
wherein said yield is calculated separately in a case where said one or more redundancy repairs are provided as bit repair and in a case where said redundancy repairs are provided as word repair.

9. The redundancy repaired yield calculation method of claim 1,
wherein said yield is calculated with respect to each layer included in said memory cell array.

10. A yield calculation method for calculating a yield by using the redundancy repaired yield calculation method of claim 1, comprising a step of:
calculating a total yield of said memory cell array by:
calculating a first yield attained when said one or more redundancy repairs are not provided by using a probability that a failure-related defect occurs in none of layers included in said memory cell array;
calculating a second yield attained when said one ore more redundancy repairs are provided by using the redundancy repaired yield calculation method; and
obtaining a sum of said first yield and said second yield.

11. A method for determining a number of redundancy repairs to be provided by using the redundancy repaired yield calculation method of claim 1, comprising a step of:
determining the number of redundancy repairs to be actually provided to said memory cell array on the basis of a relationship between a number of redundancy repairs provided to said memory cell array and a yield calculated by using the redundancy repaired yield calculation method.
